(19) United States
(12) Patent Application Publication
(10) Pub. No.: US 2005/0134406 A1
(43) Pub. Date: Jun. 23, 2005

(54) Piezoelectric thin film resonator and method for manufacturing the same

(75) Inventor: Kenji Inoue, Tokyo (JP)

Correspondence Address: OLIFF & BERRIDGE, PLC, P.O. BOX 19928, ALEXANDRIA, VA, 22320, US

(73) Assignee: TDK CORPORATION, Chuo-ku (JP)

(21) Appl. No.: 10/995,362

(22) Filed: Nov. 24, 2004

(30) Foreign Application Priority Data
Nov. 25, 2003 (JP) P2003-393548

(51) Int. Cl. H03H 9/54

(52) U.S. Cl. 333/187

(57) ABSTRACT

A piezoelectric thin film resonator 10 has a device substrate 11 and multilayer films 12 to 15, containing a piezoelectric film 14, formed on the device substrate 11. The piezoelectric thin film resonator 10 generates a signal of predetermined resonance frequency using bulk acoustic wave propagating inside the piezoelectric film 14. The end face of the multilayer film 12 is positioned inward from the end face of the device substrate 11. With the configuration, a handling tool 16 does not contact with the multilayer films 12 to 15 when handling the piezoelectric thin film resonator 10, which prevents the multilayer films 12 to 15 from damages such as film-separation.

### BACKGROUND OF THE INVENTION

1. Field of the Invention

The present invention relates to a piezoelectric thin film resonator and a method for manufacturing the same, specifically to a technology effective in preventing damages of thin film in the piezoelectric thin film resonator.

2. Related Background of the Invention

There is a growing demand of filters in small size, giving low loss, and having a wide pass bandwidth to cope with the recent movement toward the high-speed and large-capacity communication. Responding to the request, SAW filters are widely used with the features of small size and low loss using surface acoustic wave (SAW). The SAW filter adopts an interdigital transducer on a piezoelectric substrate to excite and receive SAW, which is formed by arranging alternately electrode fingers having an approximate width of one-fourth of the propagating SAW wavelength.

Responding to the ever-increasing request for large capacity communication, the operating frequency becomes higher than ever. Cell-phones in recent years adopt 2 GHz band of operating frequency, and currently further high frequencies are demanded.

The electrode finger width of SAW filter with 2 GHz, however, remains at about 0.4 μm. To satisfy further high frequencies, the electrode finger of 0.4 μm or less should be formed with high accuracy, which significantly reduce the productivity.

In this situation, piezoelectric thin film resonator filters using bulk acoustic wave (BAR) have been introduced. The operating frequency of the piezoelectric thin film resonator filters depends on the thickness of piezoelectric layer interposed between I/O electrodes. Conventional resonators using ceramics and quartz are, however, not used for high frequency applications because piezoelectric layer is difficult to accurately finish in thin shape. To the contrary, the piezoelectric layer in the piezoelectric thin film resonator filter is formed by use of a deposition apparatus such as sputtering apparatus so that a desired thickness of piezoelectric film is attained accurately, thus the piezoelectric thin film resonator filter establishes superiority in high frequency applications.

The electrode used in the piezoelectric thin film resonator filter is a flat-plate electrode, without need of narrow electrode as required in SAW filter, thus the piezoelectric thin film resonator filter uses large power signals.

The piezoelectric thin film resonator is disclosed in, for example, Japanese Patent Laid-Open Nos. 2002-232253 and 10-270979.

### SUMMARY OF THE INVENTION

The SAW filter may be structured by only a single layer of electrode film for an interdigital transducer. That is, the SAW filter is fabricated by forming an electrode film for an interdigital transducer over the whole surface of a piezoelectric substrate, then by forming a resist-pattern for an interdigital transducer, wiring and signal extracting electrode, and by applying etching such as RIE. Since the thin film pattern necessary as the device is formed inside the area of the substrate, the end face of the thin film is not positioned at the end face section of the piezoelectric substrate.

Consequently, when an integrated substrate such as wafer is cut to pieces, the thin film formed on the integrated substrate does not contact with the dicing blade. Therefore, film peeling hardly occurs. Furthermore, absence of thin film at end face of the substrate induces very little film peeling during transportation of the pieces and mount of the pieces to package even if handling tools such as transport arm and collet for flip chip touch the end face of the substrate.

On the other hand, the piezoelectric thin film resonator filter (piezoelectric thin film resonator) is structured by a plurality of thin films 12 to 15 formed on an device substrate 11, as shown in FIG. 9. With that structure, it is difficult in terms of cost to give a step of, on forming individual films, avoiding the presence of thin film at end face of the substrate on cutting the substrate to pieces. As a result, the end face of many thin films (acoustic reflecting films 12 in this case) unavoidably comes to the end face section of the device substrate 11.

Thus, when the piezoelectric thin film resonator is picked up by a handling tool 16 such as transport arm in the step of cutting the substrate to pieces or in the mounting step, the handling tool 16 contacts with the thin film 12 to induce film peeling to cause defects, (refer to FIG. 10.)

Even if no film peeling occurs, the film is damaged to generate cracks between layers, which cracks become origin of propagated cracks and bulging sections resulted from expansion/compression caused by, for example, thermal history, thus degrading the long period reliability.

An object of the present invention is to provide a technology to prevent damages on multilayer films in a piezoelectric thin film resonator.

A piezoelectric thin film resonator according to an aspect of the present invention comprises an device substrate and a multilayer film which includes a piezoelectric film formed on the device substrate, thus generating a signal of predetermined resonance frequency by bulk acoustic wave propagating inside the piezoelectric film, wherein the end face of the multilayer film is positioned inward from the end face of the device substrate.

According to a preferred embodiment of the present invention, the distance between the end face of the device substrate and the end face of thin film which is closest to the end face of device substrate is 1 μm or more.

According to a further preferred embodiment of the present invention, RMS of the distance between the end face of the device substrate and the end face of thin film which is closest to the end face of the device substrate is 10 μm or less.

A piezoelectric thin film resonator according to another aspect of the present invention comprises a device substrate and a multilayer film which includes a piezoelectric film formed on the device substrate, thus generating a signal of predetermined resonance frequency by bulk acoustic wave propagating inside the piezoelectric film, wherein a distal end of the device substrate side in a beveled end face of the multilayer film is positioned at or inward from the end face of the device substrate. That is, the end face of the multilayer films gives a beveled face where the end face thereof becoming close to the device substrate becomes close to the end face of the device substrate, and the distal end of the device substrate side in the beveled face is positioned along the end face of the device substrate, or the distal end of the device substrate side in the beveled face is positioned inward from the end face of the device substrate.

According to a preferred embodiment of the present invention, RMS of an angle between a device-forming face of the device substrate and a beveled-face of the multilayer film is 5 degrees or less.

A method for manufacturing a piezoelectric thin film resonator according to a further aspect of the present invention is a method a piezoelectric thin film resonator comprising a device substrate and a multilayer film which includes piezoelectric film formed on the device substrate, thus generating a signal of predetermined resonance frequency by bulk acoustic wave propagating inside the piezoelectric film. The method comprises the steps of: producing a plurality of piezoelectric thin film resonators by laminating thin films on an integrated substrate; cutting the integrated substrate along a dicing line to a half depth thereof using a first blade, (half-cutting), to separate the thin films; and fully cutting the integrated substrate to pieces, (full-cutting), along the dicing line using a second blade having a smaller thickness than that of the first blade while leaving a cut-face created by the first blade.

A method for manufacturing a piezoelectric thin film resonator according to still another aspect of the present invention is a method for manufacturing a piezoelectric thin film resonator comprising a device substrate and a multilayer film which includes a piezoelectric film formed on the device substrate, thus generating a signal of predetermined resonance frequency by bulk acoustic wave propagating inside the piezoelectric film. The method has the steps of: cutting an integrated substrate along a dicing line using a first blade to a predetermined depth to form a scrub line; producing a plurality of piezoelectric thin film resonators by laminating thin films on the integrated substrate on which the scrub-line was formed; and cutting the integrated substrate along the dicing line to pieces using a second blade which has a smaller thickness than that of the first blade under a condition of non-contacting with a side-face of the scrub-line.

A method for manufacturing a piezoelectric thin film resonator according to still further aspect of the present invention is a method for manufacturing a piezoelectric thin film resonator comprising a device substrate and a multilayer film which includes a piezoelectric film formed on the device substrate, thus generating a signal of predetermined resonance frequency by bulk acoustic wave propagating inside the piezoelectric film. The method has the steps of: producing a plurality of piezoelectric thin film resonators by selectively laminating thin films on an integrated substrate by sputtering while masking the dicing line; and cutting the integrated substrate along the dicing line to pieces using a blade under a condition of non-contacting with the thin films.

A method for manufacturing a piezoelectric thin film resonator according to still other aspect of the present invention is a method for manufacturing a piezoelectric thin film resonator comprising a device substrate and a multilayer film which includes a piezoelectric film formed on the device substrate, thus generating a signal of predetermined resonance frequency by bulk acoustic wave propagating inside the piezoelectric film. The method has the steps of: producing a plurality of piezoelectric thin film resonators by laminating thin films on an integrated substrate; removing the thin films positioned on the dicing line on the integrated substrate by etching; and cutting the integrated substrate along the dicing line to pieces using a blade under a condition of non-contacting with the thin film.

### BRIEF DESCRIPTION OF THE DRAWINGS

FIG. 1 shows a cross sectional view of the piezoelectric thin film resonator in an embodiment of the present invention, along with a handling tool.

FIG. 2 shows a cross sectional view of the piezoelectric thin film resonator in another embodiment of the present invention.

FIG. 3 shows a cross sectional view of the piezoelectric thin film resonator in a further embodiment of the present invention.

FIG. 4 illustrates the method for manufacturing the piezoelectric thin film resonator in an embodiment of the present invention, in the sequential steps.

FIG. 5 illustrates the method for manufacturing the piezoelectric thin film resonator in another embodiment of the present invention, in the sequential steps.

FIG. 6 shows a perspective view of a mask used in the method for manufacturing the piezoelectric thin film resonator in a further embodiment of the present invention.

FIG. 7 illustrates a part of the manufacturing steps of the piezoelectric resonator using the mask of FIG. 6.

FIG. 8 illustrates a part of the manufacturing steps of the piezoelectric resonator using a mask having different shape from that in FIG. 6.

FIG. 9 shows a cross sectional view of a conventional piezoelectric resonator.

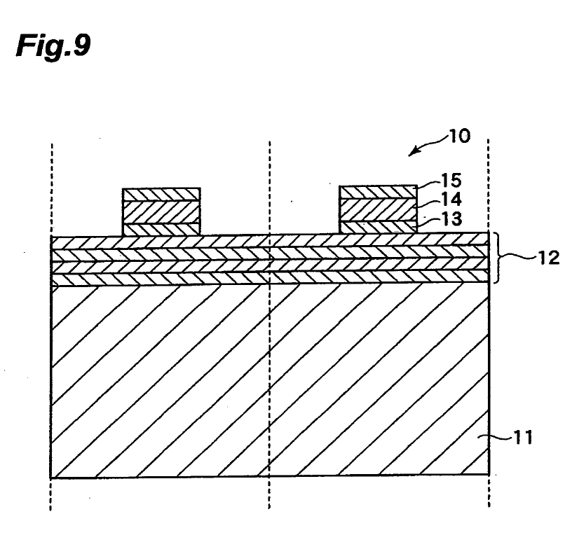

FIG. 10 illustrates the conventional piezoelectric thin film resonator after separated in pieces, along with a handling tool.

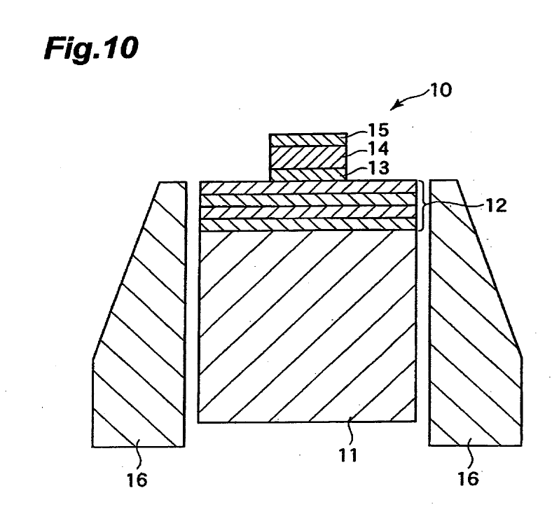

### DESCRIPTION OF THE PREFERRED EMBODIMENTS

Referring to the drawings, best embodiments for carrying out the present invention are described below in detail. For all drawings, the same member has the same symbol, and duplicated description is not given in the following. Since the description is the best embodiments for carrying out the present invention, the present invention is not limited to the embodiments.

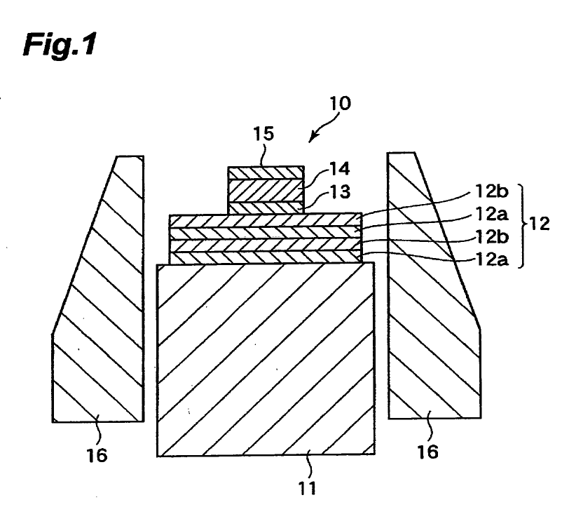

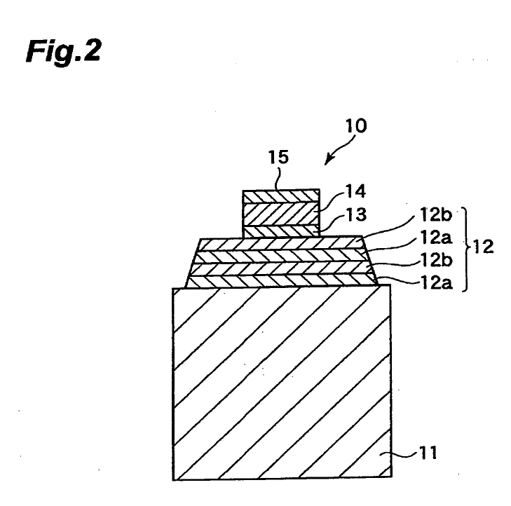

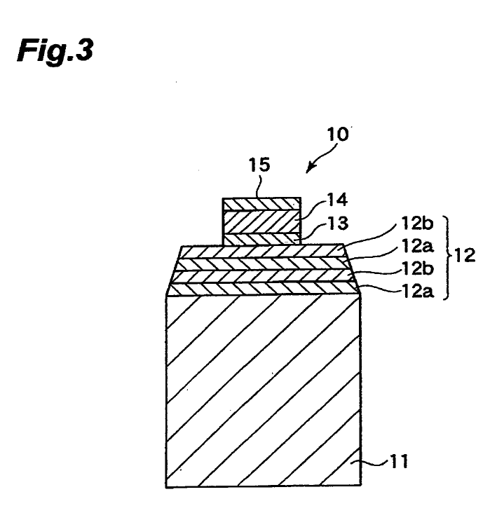

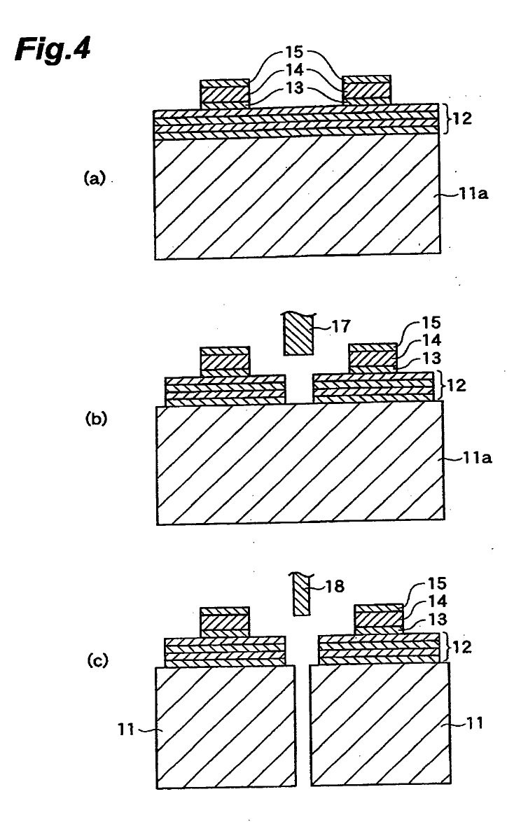

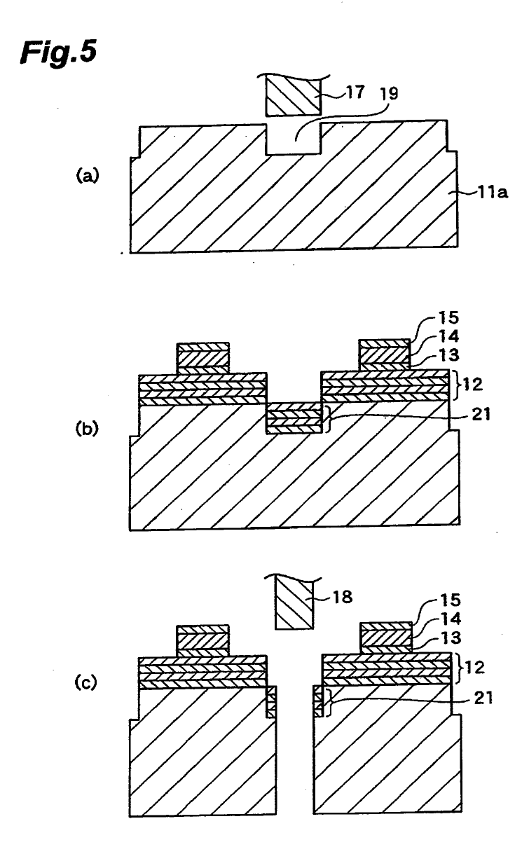

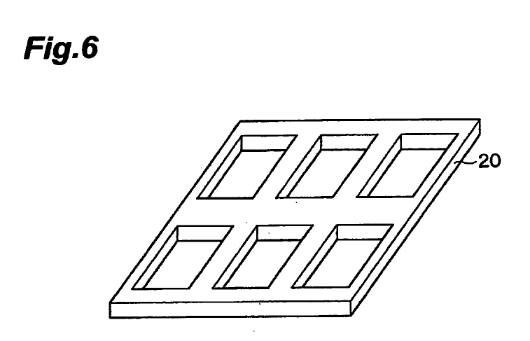

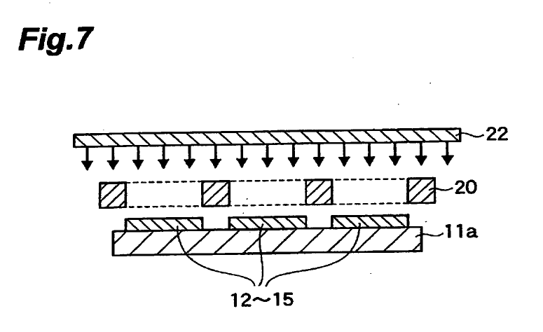

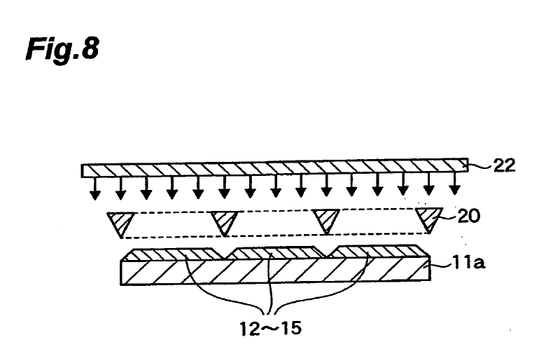

FIG. 1 shows a cross sectional view of the piezoelectric thin film resonator in an embodiment of the present invention, along with a handling tool. FIG. 2 shows a cross sectional view of the piezoelectric thin film resonator in another embodiment of the present invention. FIG. 3 shows a cross sectional view of the piezoelectric thin film resonator in a further embodiment of the present invention. FIG. 4 illustrates the method for manufacturing a piezoelectric thin film resonator in an embodiment of the present invention, in the sequential steps. FIG. 5 illustrates the method for manufacturing a piezoelectric thin film resonator in another embodiment of the present invention, in the sequential steps. FIG. 6 shows a perspective view of a mask used in the method for manufacturing a piezoelectric thin film resonator in a further embodiment of the present invention. FIG. 7 illustrates a part of the manufacturing steps of a piezoelectric resonator using the mask of FIG. 6. FIG. 8 illustrates a part of the manufacturing steps of a piezoelectric resonator using a mask having different shape from that in FIG. 6.

A piezoelectric thin film resonator 10 shown in FIG. 1 is called the solidly mounted resonator (SMR) type piezoelectric thin film resonator. An example of the SMR type piezoelectric thin film resonator is structured by the device substrate 11 made of single-crystal silicon and by an acoustic reflecting film 12 formed on the device substrate 11. The acoustic reflecting film 12 is formed by laminating total four layers of alternately stacked thin film having a high acoustic impedance and thin film having a low acoustic impedance, or an AlN film 12a and a SiO₂ film 12b. A Pt film is formed on the acoustic reflecting film 12 by vacuum vapor deposition, which is then subjected to patterning by lithography, thus forming a lower electrode 13.

Furthermore, a piezoelectric film 14 made of ZnO is formed on the lower electrode 13 by sputtering. On the piezoelectric film 14, an Al film is formed by sputtering. The Al film is then subjected to pattering by lithography to form an upper electrode 15. There may be formed an adhesion layer such as an AlN film or Cr film between the lower electrode 13 and the piezoelectric film 14 and between the piezoelectric film 14 and the upper electrode 15.

With that type of the piezoelectric thin film resonator 10 structured by the multilayer films 12 to 15, when an alternate current voltage is applied to the low electrode 13 and the upper electrode 15, the piezoelectric effect generates a signal of predetermined resonance frequency by a bulk wave propagating through inside the piezoelectric film 14.

The acoustic reflecting film 12 may not be formed. In that case, the lower electrode 13 is formed directly on the device substrate 11. According to the embodiment, the acoustic reflecting film 12 has four layers. If, however, thin films which differ in acoustic impedance from each other are laminated, the number of the thin films is not limited to four. Furthermore, the film material of each thin film is not limited to the above-described one given as an example.

As shown in the figure, in the piezoelectric thin film resonator according to the embodiment, the end face of each of the multilayer films 12 to 15 is positioned inward from the end face of the device substrate 11. That is, all the end faces of the thin films are not positioned at the end face section of the device substrate 11.

Owing to the configuration, when the piezoelectric thin film resonator is picked up by a handling tool 16 such as transport arm and collet used for the case of flip chip, the handling tool 16 does not contact with the multilayer films (acoustic reflecting film 12 in this case). As a result, damages of multilayer films, such as film peeling, are prevented.

The sections where the end face of the multilayer films is positioned inward from the end face of the device substrate 11 may not extend over the whole area of the device substrate 11, and may exist in a part thereof. For instance, only the sections of the end face of the multilayer films expected to contact with the handling tool 16 on picking up the resonator may be selectively placed inward from the end face of the device substrate 11.

According to the embodiment, to assure the state of non-contacting with the handling tool 16 when the resonator is picked up by the handling tool 16, the distance between the end face of the device substrate 11 and the end face of the thin film closest to the end face of the device substrate 11, (the acoustic reflecting film 12 in this case), is specified to 1 μm or more.

As shown in FIG. 2, in the case where the end face of the multilayer films is beveled, the bevel face assures avoidance of contact with the handling tool 16. Therefore, the end face of the multilayer films 12 to 15 may be positioned inward from the end face of the device substrate 11, or the distal end of the device substrate 11 side may be positioned on the end face of the device substrate 11, as shown in FIG. 3. That is, when the end face of the multilayer films 12 to 15 is beveled, the distal end of the device substrate 11 side in the beveled face may be positioned inward from the end face of the device substrate 11, or the distal end may be positioned along the end face of the device substrate 11.

Regarding a side of the device substrate 11, the distance between the end face of the device substrate 11 and the end face of the thin film (the thin film having an end face closest to the end face of the device substrate 11) formed on the device substrate 11 was measured to determine the relation between the root-mean-square (RMS) of the dispersion in the end face distance and the defects such as film peeling. The result is shown in Table 1.

TABLE 1

| | RMS (μm) | | |
|---|---|---|---|
| | 1 | 10 | 30 |
| Judgment | Good | Good | Peeling off |

Table 1 shows that the defects such as film peeling do not occur when the RMS of the end face distance is 10 μm or less. Consequently, it was found that the unevenness of the edge section of the thin film formed on the device substrate 11 causes the film separation even when the thin film is not formed on the edge section of the device substrate 11.

Then, on one side of the device substrate 11 in the piezoelectric thin film resonator having beveled end face of the multilayer films, the angle between the substrate face of the device substrate 11 and the beveled face (edge section face) of the thin films formed on the device substrate 11 was measured to determine the relation between the RMS of the angle dispersion and the defects such as film peeling. The result is given in Table 2.

TABLE 2

| | RMS (°) | | |
|---|---|---|---|
| | 5 | 10 | 15 |
| Judgment | Good | Good | Peeling off |

Table 2 shows that no defect such as film peeling occurs if RMS of the angle is 5 degrees or less. The fact revealed that film peeling occurs also on the beveled face if uniform face is not formed.

The piezoelectric thin film resonator having the structure described above is fabricated by, for example, first to fourth methods given below.

The first manufacturing method is illustrated in FIG. 4. According to the first method, thin films 12 to 15 are formed by laminating them on an integrated substrate 11a which is the substrate before being cut to pieces as the device substrates 11, thus forming a plurality of above-described piezoelectric thin film resonators 10, ((a) in FIG. 4). Next, the integrated substrate 11a is cut to a half-cut depth along the dicing line using a first blade 17 to separate the thin films (the acoustic reflecting film 12 in this case), ((b) in FIG. 4). Then, using a second blade 18 having a smaller thickness than that of the first blade 17 used: for separating the thin film, the integrated substrate 11a is fully cut along the dicing line to pieces while leaving the cut face created by the first blade 17, ((c) in FIG. 4).

The second manufacturing method is shown in FIG. 5. According to the second method, before forming the thin films, the integrated substrate 11a is cut to a predetermined depth along the dicing line using the first blade 17 to form a scrub line 19, ((a) in FIG. 5). Then, the thin films 12 to 15 are formed by laminating them on the integrated substrate 11a having the formed scrub line to prepare a plurality of piezoelectric thin film resonators, ((b) in FIG. 5)). Thus a thin film 21 is formed on the scrub line 19, which thin film 21 is discontinuous from the thin films 12 to 15 formed in the regions other than the scrub line section. After forming the film, the second blade 18 having a smaller thickness than that of the first blade 17 is used to cut the integrated substrate 11a along the dicing line to pieces while avoiding contacting with the cut-face on the scrub line 19, ((c) in FIG. 5).

According to the second method, since the thin film 21 on the scrub line 19 is not continuous with the thin films 12 to 15, even when the film at edge of the device substrate 11 or the thin film 21 on the scrub line 19 peels off, the peeling does not develop to the thin films 12 to 15 which contribute to the element functions. Since the thin film 21 on the scrub line 19 is a thin film independent of the element functions, the specification distinguishes the thin film 21 from the multilayer film of thin films 12 to 15 to generate a signal of predetermined resonance frequency by a bulk wave. That is, the multilayer films 12 to 15 to generate a signal of predetermined resonance frequency designate the thin films contributing to the actual device functions, thus they do not include the thin film 21 formed on the scrub line 19.

According to the third manufacturing method, the dicing line is masked by a mask 20, for example, as shown in FIG. 6, then the thin films 12 to 15 are formed by laminating them selectively on the integrated substrate 11a by sputtering a sputter target 22, as shown in FIG. 7, to prepare a plurality of piezoelectric thin film resonators. After that, a blade (not shown) is used to cut the substrate along the dicing line to pieces while avoiding contacting between the blade and the thin films 12 to 15. If a beveled face is formed on the thin films 12 to 15 using sputtering, the adopted mask 20 may have a triangular cross section in normal to the dicing line, having the vertex facing the integrated substrate 11a.

Regarding the fourth manufacturing method, a plurality of piezoelectric thin film resonators 10 is prepared by forming laminated thin films 12 to 15 on the integrated substrate 11a, (refer to (a) in FIG. 4), then the thin films 12 to 15 on the dicing line on the integrated substrate 11a are removed by dry-etching or wet-etching. After that, a blade is used to cut the integrated substrate 11a along the dicing line to pieces while avoiding touching the blade with the thin films 12 to 15.

The above-given four kinds of manufacturing methods are only examples, and other methods may also be applied to manufacture the piezoelectric thin film resonator 10 having the above-described structure.

The above-given description deals with the application of the present invention to an SMR type piezoelectric thin film resonator. The present invention, however, is applicable to general piezoelectric thin film resonators of lamination type using a piezoelectric film, including diaphragm type and air gap type piezoelectric thin film resonators which have a structure of piezoelectric film interposed between upper and lower electrodes while leaving the upper and lower faces thereof open to atmosphere, thus establishing acoustic total reflection conditions.

The present invention provides the effect of preventing damages of multilayer film, such as film peeling, because the handling tool does not contact with the multilayer film when handing the piezoelectric thin film resonator.

1. A piezoelectric thin film resonator comprising a device substrate and a multilayer film which includes a piezoelectric film formed on the device substrate, thus generating a signal of predetermined resonance frequency by bulk acoustic wave propagating inside the piezoelectric film,
wherein an end face of the multilayer film is positioned inward from an end face of the device substrate.

2. The piezoelectric thin film resonator according to claim 1, wherein the distance between the end face of the device substrate and an end face of thin film which is closest to the end face of device substrate is 1 μm or more.

3. The piezoelectric thin film resonator according to claim 1, wherein RMS of the distance between the end face of the device substrate and an end face of thin film which is closest to the end face of device substrate is 10 μm or less.

4. A piezoelectric thin film resonator comprising a device substrate and a multilayer film which includes a piezoelectric film formed on the device substrate, thus generating a signal of predetermined resonance frequency by bulk acoustic wave propagating inside the piezoelectric film,
wherein a distal end of the device substrate side in a beveled end face of the multilayer film is positioned at or inward from the end face of the device substrate.

5. The piezoelectric thin film resonator according to claim 4, wherein RMS of an angle between a device-forming face of the device substrate and a beveled-face of the multilayer film is 5 degrees or less.

6. A method for manufacturing a piezoelectric thin film resonator comprising a device substrate and a multilayer film which includes piezoelectric film formed on the device substrate, thus generating a signal of predetermined resonance frequency by bulk acoustic wave propagating inside the piezoelectric film,
the method comprising the steps of:
producing a plurality of piezoelectric thin film resonators by laminating thin films on an integrated substrate;
cutting the integrated substrate along a dicing line to a half depth thereof using a first blade to separate the thin films; and
fully cutting the integrated substrate to pieces along the dicing line using a second blade having a smaller thickness than that of the first blade while leaving a cut-face created by the first blade.

7. A method for manufacturing a piezoelectric thin film resonator comprising a device substrate and a multilayer film which includes a piezoelectric film formed on the device substrate, thus generating a signal of predetermined resonance frequency by bulk acoustic wave propagating inside the piezoelectric film,
the method comprising the steps of:
cutting an integrated substrate along a dicing line using a first blade to a predetermined depth to form a scrub-line;
producing a plurality of piezoelectric thin film resonators by laminating thin films on the integrated substrate on which the scrub-line was formed; and
cutting the integrated substrate along the dicing line to pieces using a second blade which has a smaller thickness than that of the first blade under a condition of non-contacting with a side-face of the scrub-line.

8. A method for manufacturing a piezoelectric thin film resonator comprising a device substrate and a multilayer film which includes a piezoelectric film formed on the device substrate, thus generating a signal of predetermined resonance frequency by bulk acoustic wave propagating inside the piezoelectric film,
the method comprising the steps of:
producing a plurality of piezoelectric thin film resonators by selectively laminating thin films on an integrated substrate by sputtering while masking the dicing line; and cutting the substrate along the dicing line to pieces using a blade under a condition of non-contacting with the thin films.

9. A method for manufacturing a piezoelectric thin film resonator comprising a device substrate and a multilayer film which includes a piezoelectric film formed on the device substrate, thus generating a signal of predetermined resonance frequency by bulk acoustic wave propagating inside the piezoelectric film,
the method comprising the steps of:
producing a plurality of piezoelectric thin film resonators by laminating thin films on an integrated substrate;
removing the thin films positioned on the dicing line on the integrated substrate by etching; and
cutting the integrated substrate along the dicing line to pieces using a blade under a condition of non-contacting with the thin films.
